(19) United States
(12) Patent Application Publication
(10) Pub. No.: US 2016/0351440 A1
(43) Pub. Date: Dec. 1, 2016

(54) METHOD OF MANUFACTURING SEMICONDUCTOR DEVICE

(71) Applicant: Kabushiki Kaisha Toshiba, Minato-ku (JP)

(72) Inventor: Takamichi TSUCHIYA, Yokkaichi (JP)

(73) Assignee: Kabushiki Kaisha Toshiba, Minato-ku (JP)

(21) Appl. No.: 14/845,874

(22) Filed: Sep. 4, 2015

(30) Foreign Application Priority Data
May 28, 2015 (JP) 2015-108850

(51) Int. Cl. H01L 21/768; H01L 27/115; H01L 23/532

(52) U.S. Cl. CPC H01L 21/76816; H01L 21/76877; H01L 21/76892; H01L 23/53214; H01L 23/53257; H01L 27/11521; H01L 27/11568; H01L 27/11526; H01L 27/11573

(57) ABSTRACT

According to one embodiment, a method of manufacturing a semiconductor device comprises forming a first insulating film and a wiring pattern and forming a second insulating film on the upper side of these. Further, a process of making holes in the second insulating film simultaneously at position where the wiring pattern is placed and position where the wiring pattern is not formed is performed. Thus, a first hole extending down to the wiring pattern and a second hole extending down to the first insulating film are formed. Then part of the first insulating film is removed through the second hole, and forming an air gap between a first portion and a second portion of the wiring pattern.

### CROSS-REFERENCE TO RELATED APPLICATIONS

This application is based upon and claims the benefit of priority from Japanese Patent Application No. 2015-108850, filed on May 28, 2015; the entire contents of which are incorporated herein by reference.

### FIELD

Embodiments described herein relate generally to a method of manufacturing a semiconductor device.

### BACKGROUND

As semiconductor devices become finer in these years, capacitance between lines of a wiring layer tends to increase. If the between-line capacitance increases, parasitic capacitance of the circuit increases, so that the operation speed of the semiconductor device decreases. As one method of reducing this between-line capacitance, there is a method which provides air gaps between lines.

However, manufacturing a semiconductor device provided with air gaps needs a large number of process steps to form air gaps. Thus, a semiconductor device provided with air gaps is difficult to manufacture.

### BRIEF DESCRIPTION OF THE DRAWINGS

FIG. 1A is a diagram (1) for explaining a process procedure of manufacturing a semiconductor device according to an embodiment;

FIG. 1B is a diagram (2) for explaining the process procedure of manufacturing the semiconductor device according to the embodiment;

FIG. 1C is a diagram (3) for explaining the process procedure of manufacturing the semiconductor device according to the embodiment;

FIG. 1D is a diagram (4) for explaining the process procedure of manufacturing the semiconductor device according to the embodiment; and

FIG. 2 is a diagram for explaining the placement position of an air gap stop.

### DETAILED DESCRIPTION

According to one embodiment, a method of manufacturing a semiconductor device is provided which comprises forming a wiring pattern placed between a first insulating film over a substrate. Further, a second insulating film is formed on the upper side of the wiring pattern. Then a process of making holes in the second insulating film simultaneously at position where the wiring pattern is placed and position where the wiring pattern is not formed is performed. Thus, a first hole extending through the second insulating film down to the wiring pattern and a second hole extending through the second insulating film down to the first insulating film are formed. Then part of the first insulating film is removed through the second hole, and forming an air gap between a first portion and a second portion of the wiring pattern.

The method of manufacturing a semiconductor device according to an embodiment will be described in detail below with reference to the accompanying drawings. The present invention is not limited to this embodiment.

### Embodiment

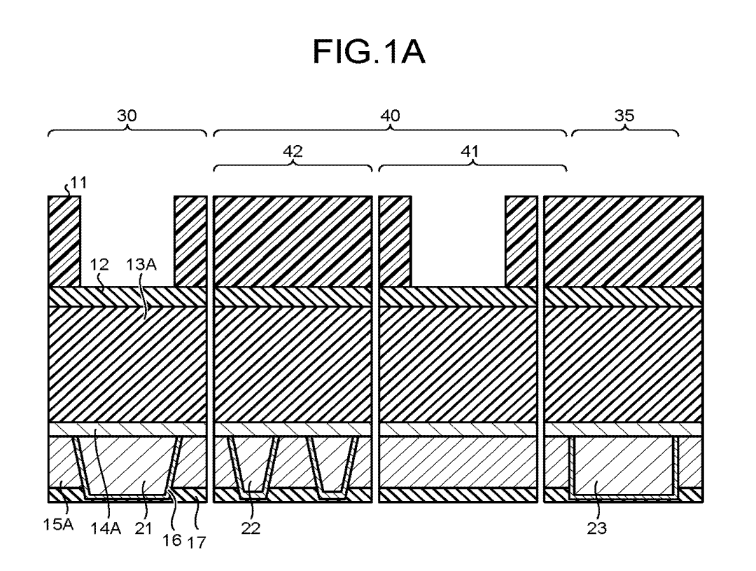

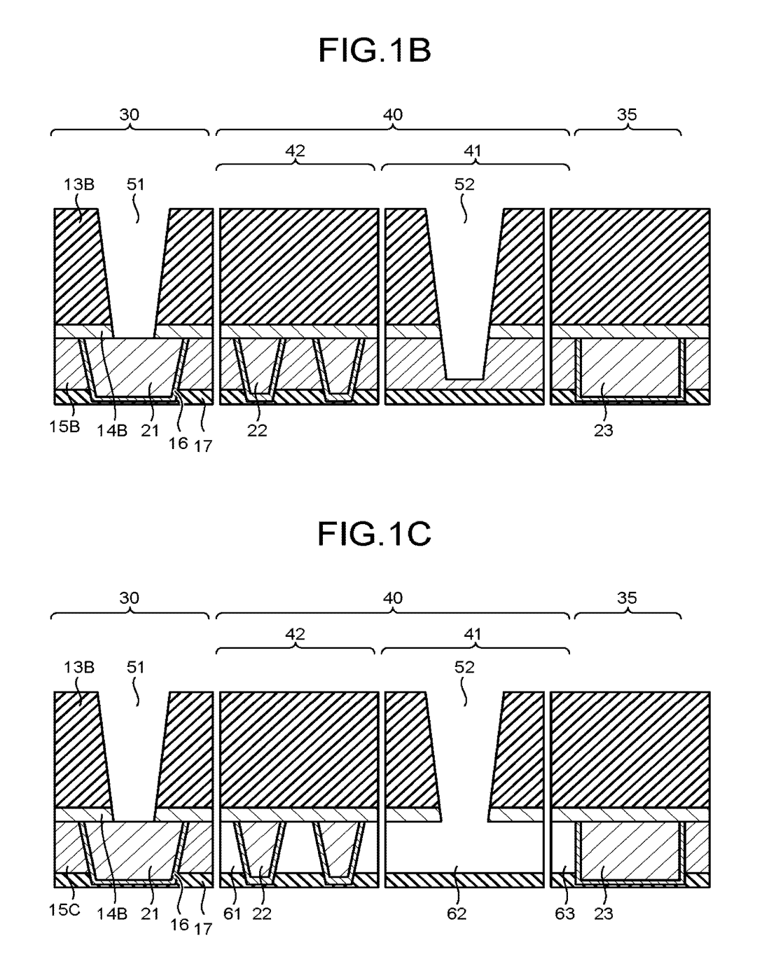

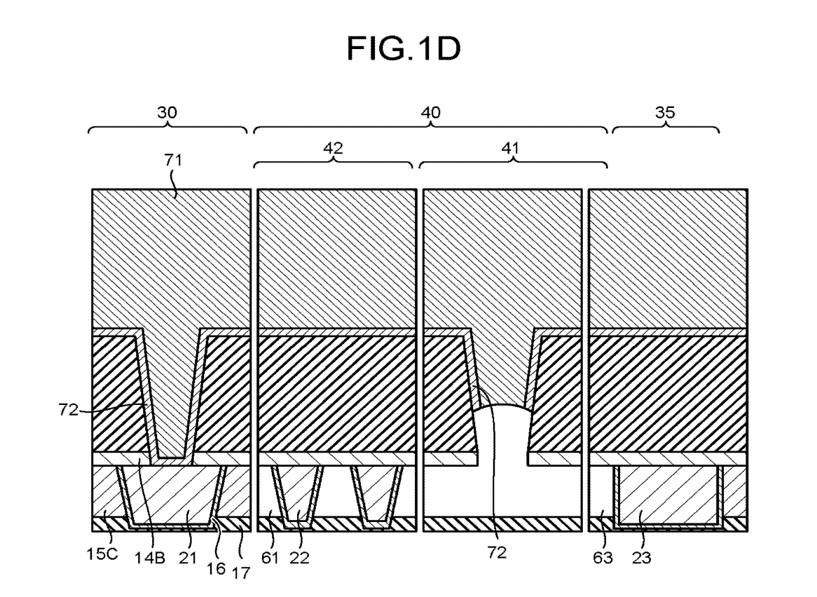

FIGS. 1A to 1D are diagrams for explaining a process procedure of manufacturing a semiconductor device according to the embodiment. FIGS 1A to 1D show the cross sections of the semiconductor device. The semiconductor device is formed on a substrate such as a wafer

As shown in FIG. 1A, the substrate on which the semiconductor device is to be formed has a peripheral area 30, a cell area 40, and a stopper area 35. The cell area 40 is an area where memory cells of a RAND memory and the like are to be placed. The peripheral area 30 is a peripheral pattern area placed in the vicinity of the cell area 40, and a circuit for making the memory cells and the like operate, etc., are to be formed therein. In the present embodiment, air gaps to reduce between-line capacitance are to be formed in the cell area 40.

The stopper area 35 is an area where an annular metal pattern (air gap stop 23) in a closed-loop shape is formed. The stopper area 35 is placed, e.g., at the boundary between the cell area 40, where air gaps are to be formed, and the peripheral area 30, where air gaps are not to be formed. The air gap stop (dividing pattern) 23 is a ring-shaped wall pattern (metal ring) surrounding the cell area 40. The air gap stop 23 prevents a removal agent used to form air gaps from entering.

The removal agent used to form air gaps is sent into the cell area 40. This removal agent is confined in the cell area 40 by the air gap stop 23 so as not to enter the lower layer side in the peripheral area 30. The cell area 40 has a cell pattern area 42 where memory cells are to be formed and a non-cell pattern area 41 where memory cells are not to be formed.

In manufacturing the semiconductor device, an interlayer insulating film 17 that is a first layer is formed on the substrate, and an interlayer insulating film 15A that is a second layer is formed on top of the interlayer insulating film 17. The interlayer insulating film 17 is an insulating film of, e.g., DTEOS (Densified Tetra Ethyl Ortho Silicate) or the like. The interlayer insulating film 15A is an insulating film of, e.g., amorphous silicon, carbon-based material, or the like. Predetermined regions of the interlayer insulating film 15A are removed by a subsequent process, and the cleared regions form air gaps.

After the interlayer insulating films and 15A are formed, a wiring pattern is formed. In forming the wiring pattern, groove patterns are formed in the peripheral area 30, the cell pattern area 42, and the stopper area 35. The groove patterns are formed extending through the interlayer insulating film 15A to the interlayer insulating film 17. Earner metal 16 is deposited over the side wall surfaces and bottoms of the formed groove patterns. Then a metal film is filled in the grooves covered by the barrier metal 16.

The groove patterns in the peripheral area 30 are filled with the metal film to form metal wiring patterns 21. The groove patterns in the cell pattern area 42 are filled with the metal film to form bit lines 22. The groove pattern in the stopper area 35 is filled with the metal film to form the air gap stop 23 The metal wiring patterns 21, the bit lines 22, and the air gap stop 23 are formed of, e.g., Cu (copper).

The metal wiring patterns 21, the bit lines 22, and the air gap stop 23 are formed simultaneously. The interlayer insulating film 15A may be formed after the metal wiring patterns 21, the bit lines 22, and the air gap stop 23 are formed. After the metal wiring patterns 21, the bit lines 22, the air gap stop 23, and the interlayer insulating film 15A are formed, a cap layer 14A is formed over these films to cover the entire surface of the substrate. The cap layer 14A prevents the metal film filled in the groove patterns from diffusing into the upper side thereof and improves the reliability of the metal film. The cap layer 14A is made of, e.g., SiCN. The formation of the cap layer 14A may be omitted depending on the type of the metal film used for the metal wiring patterns 21, the bit lines 22, and the air gap stop 23.

After the cap layer 14A is formed, an interlayer insulating film 13A that is a third layer is formed to cover the entire surface of the cap layer 14A. The interlayer insulating film 13A is an insulating film of a different type than the interlayer insulating film 15A, such as DTEOS. After the interlayer insulating film 13A is formed, a BARC (Bottom Anti-Reflective Coating) 12 that is an antireflective film is formed to cover the entire surface of the interlayer insulating film 13A.

Then a resist is coated to cover the entire surface of the BARC 12. Then by patterning the resist, a resist pattern 11 is formed. The resist pattern 11 has openings at positions over the metal wiring pattern 21 and where hole patterns (via hole patterns) are to be formed (hereinafter called hole positions). Further, in the present embodiment, the resist pattern 11 has openings at positions through which the removal agent used to form air gaps is to be injected (hereinafter called removal-agent injecting positions). The removal-agent injecting positions are pc ions under which the metal film including the metal wiring patterns 21, the bit lines 22, the air gap stop 23, etc., not placed. Here, for example, the hole positions are set to be in the peripheral area 30, and the removal-agent injecting positions are set to be in the non-cell pattern area 41 of the cell area 40.

After the resist pattern 11 is formed, etching is performed with the resist pattern 11 as a mask as shown in FIG. 1B. Thus, regions corresponding to the opening positions of the resist pattern 11 are etched. Specifically, regions of the BARC 12, the interlayer insulating film 13A, and the cap layer 14A corresponding the hole positions and the removal-agent injecting positions are etched to leave holes.

At the hole positions the metal wiring patterns 21 are formed, and hence etching stops at the upper surfaces of the metal wiring patterns 21. In contrast, at the removal-agent injecting positions no metal film is placed, and hence etching advances to the upper surface, or a point along the height, of the interlayer insulating film 15A. Thus, the interlayer insulating film 13A becomes an interlayer insulating film 13B having holes made at predetermined positions. The layer 14A becomes a cap layer 14B having holes made at predetermined positions. The interlayer insulating film 15A becomes an interlayer insulating film 15B having holes made extending to predetermined positions.

After regions of the interlayer insulating film 13A and the like corresponding to the hole positions and the removal-agent injecting positions are etched, the resist pattern 11 and the BARC 12 are removed. Thus, opening patterns 51 are formed at the hole positions, and opening patterns 52 are formed at the removal-agent injecting positions.

After the opening patterns 51, 52 that are holes are formed, air gaps 61 to 63 are formed as shown in FIG. 1C. In forming the air gaps 61 to 63, the removal agent is sent into the opening patterns 51, 52. The removal agent selectively performs isotropic etching on the interlayer insulating film 15B. The removal of the interlayer insulating film 15B by the removal agent may be wet etching, or down-flow-type chemical dry etching using a radical such as oxygen, nitrogen, or hydrogen as an etchant, or ashing using an ashing gas.

If the interlayer insulating film 15B is made of amorphous silicon, a TMY (trimethy-2-hydroxyethylammonium hydroxide) water solution or the like is used as the removal agent. If the interlayer insulating film 155 is made of a carbon-based material, an ashing gas other than an oxygen-based gas (e.g., a hydrogen-based ashing gas) or the like is used for an ashing gas as a removal agent.

The removal agent sent into the opening patterns 51 stops at the upper surface of the metal wiring pattern 21 and does not go in further downward than the metal wiring pattern 21. Thus, the removal agent does not touch the interlayer insulating film 155 in the peripheral area 30. As a result, the interlayer insulating film 155 in the peripheral area 30 remains without being removed. Thus, EM (electromigration) resistance in the peripheral area 30 is not reduced.

Meanwhile, the removal agent sent into the opening patterns 52 touches the interlayer insulating film 153 in the cell area 40. Then the removal agent removes part of the interlayer insulating film 15B in the cell area 40 from the substrate. Thus, regions clear of part of the interlayer insulating film 15B in the cell area 40 are empty spaces (air gaps 61 to 63). The air gaps 61 to 63 are spaces surrounded by the cap layer 14B, the interlayer insulating film 17, and wall surfaces of the bit lines 22. As a result, the interlayer insulating film 15B becomes an interlayer insulating film 15C having the air gaps 61 to 63.

On the substrate, the air gap 61 is formed in the cell pattern area 42, and the air gaps 62, 63 are formed in the non-cell pattern area 41. As such, by forming the air gaps 61 to 63, part of the interlayer insulating film 153 between the bit lines 22 is removed, so that the between-line capacitance of the bit lines 22 placed in the cell area 40 can be reduced.

Thereafter, barrier metal 72 is deposited over the side wall surfaces and bottom of the opening patterns 51, 52 as shown in FIG. 1D. A metal film 71 of aluminum, tungsten, or the like is filled in the openings covered by the barrier metal 72. For example, if the metal film 71 is of aluminum, Ti/TiN/Ti or the like is deposited as the barrier metal 72 before the metal film 71 is filled. If the metal film 71 is of tungsten, TiN or the like is deposited as the barrier metal 72 before the metal film 71 is filled. The barrier metal 72 and the metal film 71 are filled down to the bottom in the opening pattern 51. Thus, the metal film 71 is connected to the metal wiring pattern 21 via the barrier metal 72. The opening pattern 52 has a higher aspect ratio than the opening pattern 51. Hence, the barrier metal 72 and the metal film 71 are not filled down to the bottom in the opening pattern 52, but the upper portion of the opening pattern 52 is filled with the metal film 71, so that the mouth of the opening pattern 52 is blocked. Thereafter, the metal film 71 is patterned to become an upper-layer wiring pattern connected to the metal wiring pattern 21.

As described above, in the present embodiment, the opening pattern 51 at the hole position for the metal wiring pattern 21 and the opening pattern 52 for the air gaps 61 to 63 are formed simultaneously. Further, because the air gap stop 23 is placed, part of the interlayer insulating film 158 in the cell area 40 is removed by the removal agent, and part of the interlayer insulating film 158 in the peripheral area 30 remains without being removed. Then the metal film 71 is filled in the opening patterns 51 and 52 simultaneously.

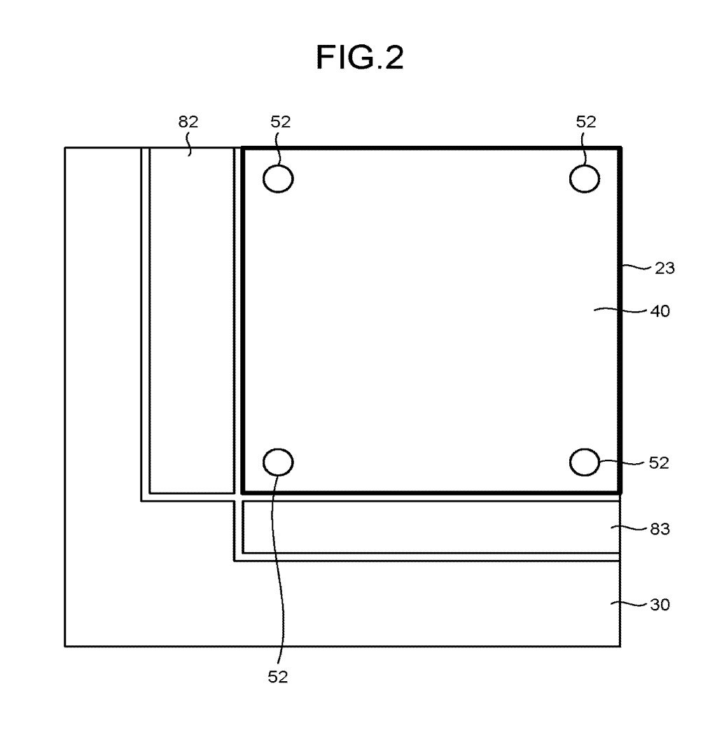

Next, the placement position of the air gap stop 23 will be described. FIG. 2 is a diagram for explaining the placement position of the air gap stop. The air gap stop 23, the peripheral area 30, and the cell area 40 are placed on a substrate on which a semiconductor device is to be formed. Further, a row decoder area 82 and a sense amplifier area 83 are placed on the substrate.

The row decoder area 82 is an area where a row decoder is to be placed. The row decoder selects a given word line from among multiple word lines to cause current to flow through cells. The sense amplifier area 83 is an area where sense amplifiers are to be placed. The sense amplifier detects and amplifies a current flowing from a cell via a bit line.

The air gap stop 23 is an approximately rectangular-ring-shaped pattern and placed surrounding part of the interlayer insulating film 155 in the cell area 40. The row decoder area 82 and the sense amplifier area 83 are placed between the peripheral area 30 and the cell area 40.

The opening patterns 52 are provided in the cell area 40, and the removal agent is sent in through the opening patterns 52 to the interlayer insulating film 158. Note that the opening patterns 51 and the like are omitted from FIG. 2.

In forming the semiconductor device, air gaps may be formed in both the peripheral area 30 and the cell area 40. In this case, the air gap stop 23 is not formed over the substrate. And opening patterns through which the upper surface of the interlayer insulating film 15B is partially exposed are formed in at least one of the peripheral area 30 and the cell area 40. Note that opening patterns through which the upper surface of the interlayer insulating film 15B is partially exposed may be formed in the row decoder area 82 and the sense amplifier area 83. At this time, opening patterns through which the upper surface of the interlayer insulating film 158 is partially exposed may be formed in the row decoder area 82 and the sense amplifier area 83 at the same time as opening patterns extending to, and blocked by, the upper surfaces of the wiring patterns, and by removing part of the interlayer insulating film 158 in the row decoder area 82 and in the sense amplifier area 83 through the opening patterns, air gaps may be formed between wiring patterns in the row decoder area 82 and the sense amplifier area 83. That is, opening patterns 51, 52 may be formed in the same circuit block area, and in this circuit block area, air gaps may be formed between wiring patterns by supplying the removal agent through openings to remove part of the interlayer insulating film 158, and the metal film 71 may be filled down to the bottom in openings formed at hole positions on the wiring patterns. Further, this setting of hole positions and removal-agent injecting positions in the same circuit block area may be applied to the cell area 40, so that both opening patterns 51, 52 are formed in the cell area 40.

Or without forming the air gap stop 23, the air gaps 61 to 63 may be formed only in the cell area 40. In this case, the removal agent is sent in through the opening patterns 52 in the cell area 40. Then at the time point when the air gaps 61 to 63 have been formed in the cell area 40, the formation of the air gaps 61 to 63 is stopped so that air gaps are not formed in the peripheral area 30.

The metal film 71 may be filled in the opening patterns 51, 52 simultaneously or separately. In the case of filling in them separately, the metal films filled in the opening patterns 51, 52 may be of the same material or different materials.

Or the air gap stop 23 may surround an area other than the cell area 40, not being limited to surrounding the cell area 40. For example, the air gap stop 23 may surround at least one of the peripheral area 30, the row decoder area 82, and the sense amplifier area 83 without surrounding the cell area 40.

The metal pattern, metal films, and metal wiring patterns 21 described in the present embodiment may be formed of any material as long as it is a conductive material, not being limited to a metal material.

The wiring patterns of the peripheral area 30 and other areas than the peripheral area 30 are electrically connected to each other via lower-layer wiring patterns formed on the lower side of the metal wiring patterns 21 or upper-layer wiring patterns formed on the upper side of the metal wiring patterns 21. Hence, for example, even where the metal wiring pattern 21 surrounds the periphery of the peripheral area 30, electrical connection between the peripheral area 30 and other areas than the peripheral area 30, e.g., electrical connection between metal wiring patterns 21 and the bit lines 22 is not affected.

While the semiconductor device is manufactured, memory cells are formed on the substrate. Further, the metal wiring patterns 21, the bit lines 22, the air gap stop 23, and the like are formed over the memory cells Then the air gaps 61 to 63, described in the present embodiment, are formed. Further, wiring patterns are formed of the metal film 71 on the upper side of the air gaps 61 to 63. In forming a pattern on the substrate, a film formation process, a lithography process, an etching process, and so on are executed. While the semiconductor device is manufactured, the film formation process, lithography process, etching process, and so on are repeated for each layer.

As such, according to the embodiment, holes are made in the interlayer insulating film 13A simultaneously at positions where the metal wiring patterns 21 are placed and positions where the bit lines 22 are not formed. The opening patterns 51 extending through the interlayer insulating film 13A down to the metal wiring patterns and the opening patterns 52 extending through the interlayer insulating film 13A down to the interlayer insulating film 15A are formed simultaneously. Further, parts of the interlayer insulating film 15B are removed through the opening patterns 52, so that the air gaps 61 to 63 are formed between the bit lines 22 in the cell area 40. As such, the opening patterns 51, 52 are formed simultaneously, and hence the air gaps 61 to 63 can be easily formed in the cell area 40.

Further, because the air gaps 61 to 63 are formed using the air gap stop 23, air gaps are not formed in the peripheral area 30. Thus, between-line capacitance in the cell area 40 can be reduced without reducing EM resistance in the peripheral area 30.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
forming a wiring pattern placed between a first insulating film over a substrate;
forming a second insulating film on the upper side of the wiring pattern;
performing a process of making holes in the second insulating film simultaneously at position where the wiring pattern is placed and position where the wiring pattern is not formed, and forming a first hole extending through the second insulating film down to the wiring pattern and a second hole extending through the second insulating film down to the first insulating film; and
removing part of the first insulating film through the second hole, and forming an air gap between a first portion and a second portion of the wiring pattern.

2. The method of manufacturing the semiconductor device according to claim 1, further comprising filling a conductive film of the same material in at least part of the second hole and in the first hole.

3. The method of manufacturing the semiconductor device according to claim 1, wherein the second insulating film is an insulating film of a different type than the first insulating film.

4. The method of manufacturing the semiconductor device according to claim 1, wherein the second hole is larger in aspect ratio than the first hole.

5. The method of manufacturing the semiconductor device according to claim 2, further comprising patterning the conductive film, and forming an upper-layer wiring pattern connected to the wiring pattern.

6. The method of manufacturing the semiconductor device according to claim 5, wherein the conductive film is made of aluminum or tungsten.

7. A method of manufacturing a semiconductor device comprising:
forming a first wiring pattern placed between a first insulating film in a first area over a substrate and a second wiring pattern placed between the first insulating film in a second area over the substrate;
forming a second insulating film on the upper side of the first and second wiring patterns;
performing a process of making holes in the second insulating film simultaneously at position where the first wiring pattern is placed and position where the second wiring pattern is not formed in the second area, and forming a first hole extending through the second insulating film down to the first wiring pattern and a second hole extending through the second insulating film down to the first insulating film; and
removing part of the first insulating film in the second area through the second hole, and forming an air gap between a first portion and a second portion of the second wiring pattern in the second area.

8. The method of manufacturing the semiconductor device according to claim 7, further comprising filling a conductive film of the same material in at least part of the second hole and in the first hole.

9. The method of manufacturing the semiconductor device according to claim 7, wherein the second insulating film is an insulating film of a different type than the first insulating film.

10. The method of manufacturing the semiconductor device according to claim 7, wherein the second hole is larger in aspect roil than the first hole.

11. The method of manufacturing the semiconductor device according to claim 8, further comprising patterning the conductive film, and forming an upper-layer wiring pattern connected to the first wiring pattern.

12. The method of manufacturing the semiconductor device according to claim 11, wherein the conductive film is made of aluminum or tungsten.

13. The method of manufacturing the semiconductor device according to claim 7, further comprising forming a dividing pattern that separates part of the first insulating film in the first area and part of the first insulating film in the second area.

14. The method of manufacturing the semiconductor device according to claim 13, wherein the dividing pattern is an annular pattern and is formed surrounding part of the first insulating film in the second area.

15. The method of manufacturing the semiconductor device according to claim 13, wherein the first and second wiring patterns are formed of the same material simultaneously.

16. The method manufacturing the semiconductor device according to claim 15, wherein the dividing pattern is formed of the same material, at the same time, as the firs and second wiring patterns.

17. The method of manufacturing the semiconductor device according to claim 14, wherein the first and second wiring patterns are electrically connected via a lower-layer wiring pattern below or an upper-layer wiring patterns above them.

18. The method of manufacturing the semiconductor device according to claim 7, wherein while part of the first insulating film in the second area is removed, part of the first insulating film in the first area is not removed.

19. The method of manufacturing the semiconductor device according to claim 7, wherein the second area is a cell area where memory cells are placed.

20. The method of manufacturing the semiconductor device according to claim 19, wherein the first area is a peripheral pattern area placed in the vicinity of the memory cells.
